(19) United States
(12) Patent Application Publication
(10) Pub. No.: US 2009/0145361 A1
(43) Pub. Date: Jun. 11, 2009

(54) EVAPORATION APPARATUS

(76) Inventors: Hiroki Nakamura, Chiba-ken (JP); Hiroshi Watanabe, Chiba-ken (JP)

Correspondence Address: QUARLES & BRADY LLP, 411 E. WISCONSIN AVENUE, SUITE 2040, MILWAUKEE, WI, 53202-4497, US

(21) Appl. No.: 11/911,896

(22) PCT Filed: Apr. 18, 2006
(86) PCT No.: PCT/JP2006/308503

§ 371 Date: Dec. 8, 2008

(30) Foreign Application Priority Data
Apr. 21, 2005 (JP) 2005-124315

(51) Int. Cl. C23C 16/54

(52) U.S. Cl. 118/723 VE

(57) ABSTRACT

Thermal electrons emitted the filament 331 are irradiated in the vicinity of the opening of the nozzle 311 of the sealed evaporation source 31. The vapor 242 of an evaporation material (Cu) emitted into the vacuum chamber 32 through the nozzle 311 of the sealed evaporation source 31 is ionized in the vicinity of the opening of the nozzle 311 by thermal electrons emitted from the filament 331. Moreover, the ionization produces an avalanche of electrons, thus resulting in a plasma state. Thus, the evaporation material (Cu) travels to the substrate (stainless plate 333) in the form of an inverted conical vapor (in a flight form of the evaporation material) 344 to form a deposited film of the evaporation material (Cu).

### TECHNICAL FIELD

The present invention relates to an evaporation apparatus, which utilizes plasma.

### BACKGROUND ART

As an vacuum evaporation method utilizing ions, there are the method of generating plasma in a vacuum chamber and extracting ions and the method of avoiding generation of plasma. The former is the so-called ion plating method and the latter is the so-called cluster ion beaming method.

First, an evaporation apparatus for plasma generation will be explained by referring to FIG. 6.

An open-type evaporation source (a crucible or boat) 11, which contains an evaporation material 14, is disposed within the vacuum chamber 12. A gas supply portion 122 for supplying a plasma production gas and a high-frequency coil 131 for producing an ionization effect are disposed in the vacuum chamber 12 to create a plasma state therein. A substrate support 132 for fixedly attaching the evaporation substrate 133 is disposed on the upper portion of the vacuum chamber 12.

Generally, argon is used as an auxiliary gas to be supplied. A supply amount of argon is controlled. Unnecessary gas is evacuated from the vacuum chamber 12 through the exhaust opening 121. A suitable amount of argon remains in the vacuum chamber 12.

A high-frequency power supply 152 is connected to the high-frequency coil 131 to apply the frequency and voltage suitable for plasma generation.

A dc power supply 151 is connected to the evaporation source 11 and the substrate 133, the substrate support 132. The negative voltage of the dc power supply is applied to the substrate 133 and the substrate support 132.

After the vacuum chamber 12 is once evacuated to a high vacuum state, a plasma production gas is introduced into the vacuum chamber through the gas supply section 122. The vacuum degree is reduced to the extent of the pressure at which plasma can be easily generated (roughly, to the level of 10⁻¹ Pa). With that state, when a high-frequency voltage is applied to the high-frequency coil 131, the plasma production gas generates plasma through glow discharging and the plasma expands over the plasma generation area 142.

When the evaporation material 14 in the open-type evaporation source 11 is heated and vaporized, evaporated gas (vapor) generates and diffuses above the evaporation source 11 (roughly, above the line 141) in the vacuum chamber 12. The diffused vapor collides with electrons and radicals (ionized atoms) of the plasma production gas in the plasma generation area 142, thus converting into positive ions. The resultant vapor is induced and accelerated toward the substrate support, to which a negative voltage is applied, and is irradiated onto the substrate 133 to form a deposited film. Vapor in neutral state is irradiated onto the substrate 133, together with ionized vapor, to form a deposited film.

In the evaporation by the above-mentioned method, the adhesive degree of an evaporation material to the substrate is far stronger than that in the conventional evaporation and adhesive conditions can be obtained better even to the substrate with a complicated shape. The improved adhesive degree of an evaporation material on the substrate results from the substrate surface cleaning effect by ions in a plasma production gas and from accelerated irradiation of ions of the vaporized material. Moreover, the excellent adhesive property results from the vapor, mixed with the plasma production gas, which is filled near the substrate.

The condition, where vapor is mixed with a plasma production gas, means a small average mean free path of vapor molecules. The arrival factor of vapor to a substrate becomes remarkably small due to the scattering of vapor molecules. Therefore, the use efficiency of an evaporation material is forcedly decreased. In view of the motion state of vapor, the motion of vapor, depending on a thermal energy and advancing in parallel with a substrate, disperses due to collision against the plasma production gas and loses the translation property. In the ion plating, the plasma production gas is required to utilize ionic forces. The plasma production gas contributes to improving the adhesive degree and the adhesive strength, but the use efficiency of an evaporation material is reduced. As a result, it is difficult to increase the evaporation rate. Therefore, in that method, it is important that plasma can be generated even if the amount of plasma production gas is reduced as much as possible. A high-frequency electric field having a large energy ionization effect is utilized as plasma creation means.

Argon gas to be used as a plasma production gas is costly and the formation of a deposited film through ion plating is high cost, correlatively with the slow evaporation rate. Accordingly, it is difficult to increase the production volume of evaporation.

Next, the cluster ion beam evaporation that can avoid the generation of plasma will be explained by referring to FIG. 7 (for example, refer to the patent document 1).

A sealed evaporation source 21, in which an evaporation material 24 is loaded, a filament 231 for thermal electron emission, in the vicinity of the sealed evaporation source, a grid (extracting electrode) 232 for extracting thermal electrons, an accelerating electrode 233 located between the filament and the substrate, and a substrate support 234 for fixing the substrate 235 on the accelerating electrode are arranged in the vacuum chamber 22.

A dc power supply 252 is connected between the sealed evaporation source 21 and the substrate 235 (the substrate support 234), the negative voltage being applied to the substrate 235 and the substrate support 234. A dc power source 251 is connected between the filament 231 and the grid 232 while the dc power source 252 is connected between the grid 232 and the accelerating electrode 233. The accelerating electrode 233 and the substrate 235 and the substrate support 234 are equi-potential.

The evaporation material 23 in the sealed evaporation source 21 becomes vaporized gas (vapor) 241 through heating. However, the opening (nozzle) 211 is very small, the vapor produces thermal disturbance motion in the sealed evaporation source 21, thus increasing its vapor pressure. The vapor pressure in the evaporation source 21 builds up with heating temperatures. However, when copper (Cu), for example, is heated to 1600° C. or more, the vapor pressure rises up to about 1.33×10² Pa in the evaporation source 21. When the vacuum degree in the vacuum chamber 22 is 1.33×10³ Pa, the pressure in the sealed evaporation source 21 becomes 10⁵ times the external pressure, so that the vapor is ejected at a very high velocity from the opening 211.

The ejected vapor 242 adiabatically expands. In the course of the expansion, each of molecules loses its temperature and kinetic energy, obtained through heating. Molecules attract mutually by just the loss of energy through the influence of Van der Waals' force, so that a considerable number of molecular clusters are created. The clusters advance toward the substrate 235 through the thermal electrons. In the travel, when the thermal electrons collide with clusters, they are converted into cluster ions 243 (positive ions). The cluster ions 243 more accelerate their ejection speeds, by the (negative) potential of the accelerating electrode 233 and the substrate 235 (the substrate support 234), and thus irradiate onto the substrate 235.

As to the cluster ions, one ion molecule only among clusters is a positive ion and the remaining molecules are neutral. The acceleration potential acts on one positive ion only but does not act on neutral molecules. Hence, the incident velocity to the substrate takes the value obtained by dividing the velocity of one ion by the molecular number of clusters. From a viewpoint of the mass, the whole of clusters are acted by the potential, the incident energy is far large, compared with the energy in the conventional evaporation. The clusters collapse at the moment when they impinge on the substrate, so that migration arises. As a result, a deposited film having excellent crystallizability can be obtained. Because a majority of incident molecules are neutral, the electrostatic charging amount due to ions is very small.

However, to create cluster ions, the control of an evaporation amount and the configuration and arrangement of filaments and grids for ionization should be optimized. In the explanation of the ion plating, the pressure, at which gas converts into plasma, indicates a level of about 10⁻¹ Pa. However, with the pressure in the evaporation source, which is about 1.3×10² Pa (described above), the pressure is close to the gaseous density at the moment of ejection. In such a situation, gas can be easily converted into a plasma state by the received thermal electrons. In that case, since the number of ions is very large, most clusters separate into monomolecular states or turn into a small number of molecular ensembles. Therefore, the migration effect associated with an increase or collapse of mass due to the formation of clusters cannot be expected. The electrostatic potential of a deposited film to be formed does not reduce.

In the deposition of an electrical insulator, for example, SiO, when the vaporized SiO adheres on the grid or on the acceleration electrode, the grid or the acceleration electrode becomes impotent instantly. Moreover, when the electrostatic potential, which occurs on the deposited film, repels incident ions. In the cluster ion beam deposition, it is very difficult to choose evaporation material and to set requirements.

Patent document 1: Japanese Patent publication No. 5-41698

### DISCLOSURE OF THE INVENTION

The conventional ion plating shown in FIG. 6 effectively utilizes the ion effect. However, there is the disadvantage regarding low deposition efficiency and constrains involved in the high-frequency power supply. The low deposition efficiency is the essential problem involved in the open-type evaporation source that the gas pressure necessary for plasma generation can be obtained by only the use of plasma production gas. The high-frequency power supply, means for reducing plasma production gas, cannot be used indiscriminately because the apparatus is expensive and is legally constrained in use.

The conventional cluster ion beam, shown in FIG. 7, has many technological constraints for the basic film formation and it is nearly impossible to continue the optical conditions in practical use. In other words, since an uncertainty of maintaining the vapor density is not certainly stabilized in a constant state, the relationship between the configuration and arrangement of the ionization apparatus becomes unstable. Moreover, a serious technical constraint is that deposition of electrical insulator is impossible.

Therefore, the present invention aims at paying attention to the ion effect in plasma proven in the conventional ion plating and daringly utilizing the plasma phenomenon avoided in the cluster ion beam technique and effectively utilizing ions over the conventional ion plating method.

### MEANS FOR SOLVING THE PROBLEMS

According to the present invention, to achieve the above-mentioned object, an evaporation apparatus of claim 1 comprises means for converting the ejected vapor into plasma state, wherein vapor ejected from an ejection opening of a sealed evaporation source is deposited over a substrate to form a deposited film.

Claim 2 sets forth the evaporation apparatus of claim 1, wherein the means for converting ejected vapor into plasma state comprises a power supply connected between the sealed evaporation source and the substrate.

Claim 3 sets forth the evaporation apparatus of claim 1, wherein the means for converting ejected vapor into plasma state comprises a thermal electron generation filament, which is disposed near the sealed evaporation source.

Claim 4 sets forth the evaporation apparatus of claim 1, wherein the means for converting ejected vapor into plasma state comprises a high-frequency coil, which is disposed near the sealed evaporation source.

Claim 5 sets forth the evaporation apparatus of claim 2, wherein the power supply comprises a pulse power supply.

Claim 6 sets forth the evaporation apparatus of claims 1-5, further comprises an ejection opening for reaction gas which is disposed near the ejection opening of the sealed evaporation source.

### EFFECT OF THE INVENTION

In the ion plating, the plasma production gas is essential. However, the present invention does not require the plasma production gas. The conventional cluster ion beam method requires the ionization section complicated in construction arrangement but the plasma formation means of the present invention is very simplified. Moreover, the present invention can produce a deposited film with a strong adhesive strength to a substrate and provide a high productivity.

The present invention produces plasma very simply by taking advantages of a high density property of vapor in the sealed evaporation source. Moreover, by extracting ions from plasma, the deposited film with an outstanding adhesive strength was successively produced under high productivity and at low costs. According to the present invention does not require the plasma production gas, which is used in the ion plating technique, and the complicated structure, which is used in the conventional ion plating beam technique.

### BRIEF DESCRIPTION OF THE DRAWINGS

FIG. 1 is a diagram illustrating the configuration of an evaporation apparatus according to a first embodiment of the present invention;

FIG. 2 is a diagram illustrating the configuration of an evaporation apparatus according to a second embodiment of the present invention;

FIG. 3 is a diagram illustrating the configuration of an evaporation apparatus according to a third embodiment of the present invention;

FIG. 4 is a diagram illustrating the configuration of an evaporation apparatus according to a fourth embodiment of the present invention;

FIG. 5 is a diagram illustrating the configuration of an evaporation apparatus according to a fifth embodiment of the present invention;

FIG. 6 is a diagram illustrating the configuration of a conventional evaporation apparatus which utilizes plasma; and

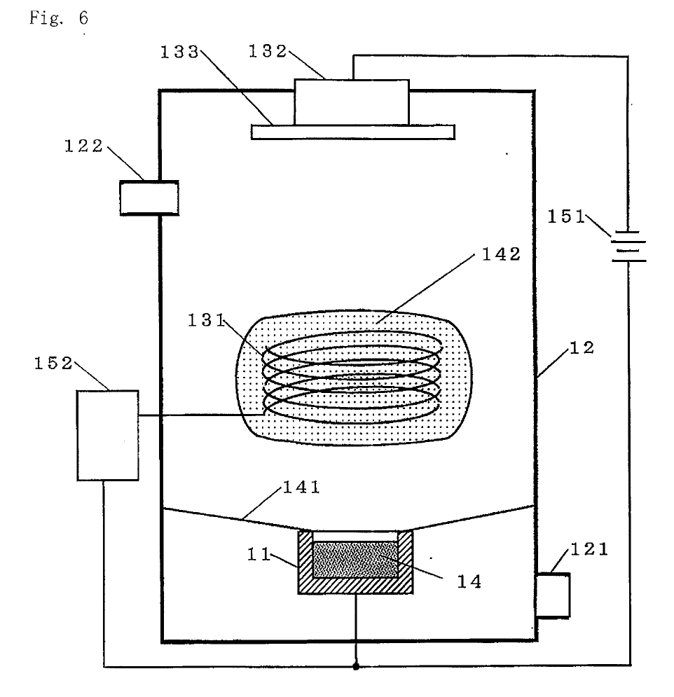

FIG. 7 is a diagram illustrating the configuration of a conventional cluster ion beam evaporation apparatus.

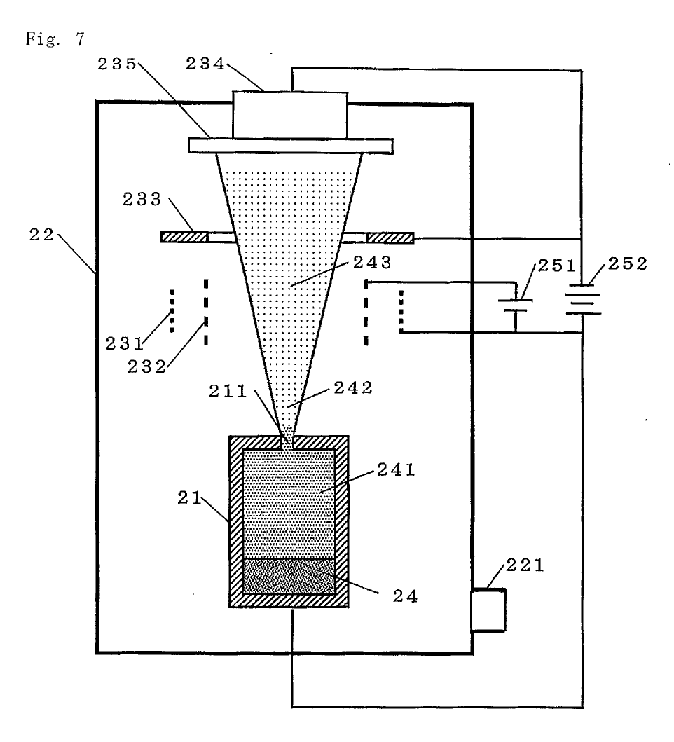

### BEST MODE FOR CARRYING OUT THE INVENTION

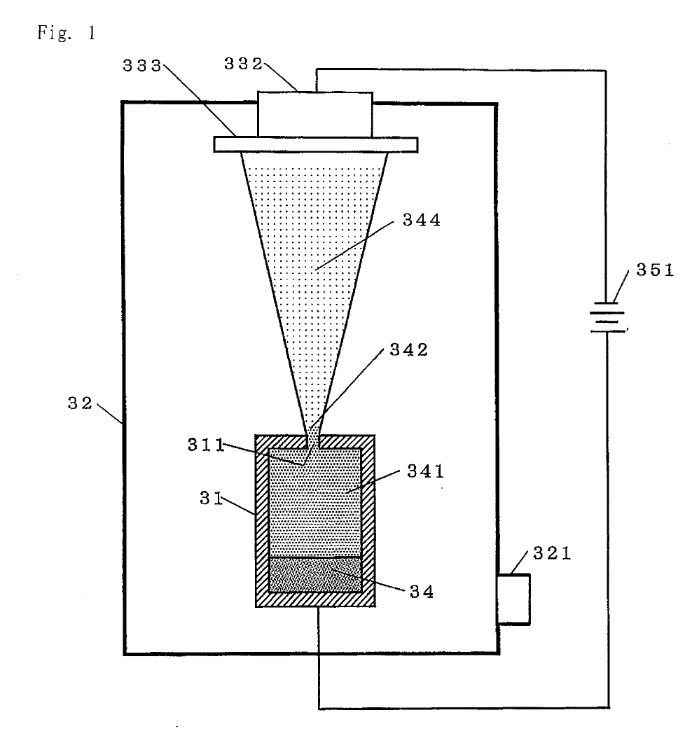

Embodiments of the present invention will be explained by referring to FIGS. 1 to 5. Like numerals are attached to the same constituent elements as those in FIGS. 1 to 5.

### Embodiment 1

FIG. 1 shows the configuration of an evaporation apparatus in the first embodiment.

The evaporation material 34. for example, Cu is placed in the sealed evaporation source 31 within the vacuum chamber 32. After gases in the vacuum chamber are evacuated through the exhaust outlet 321, the evaporation source 31 is heated. The vapor 341 of Cu fills the sealed evaporation source 31. Selecting the heating method is not specially a critical problem. The heating method may be an electron bombardment method or a resistance heating method (not illustrated). Cu, or electric conductor, allows a sufficient amount of vapor to be obtained without insulating the sealed evaporation source 31. When the heating temperature reaches at 1,600° C., the pressure in the sealed evaporation source 31 is approximately 1.33×10² Pa. The ejection opening is a nozzle 311 having a diameter of 1 mm and an inner wall to outer wall distance of 1 mm.

The vapor 342 ejected from the nozzle 311 into the vacuum chamber 32 is ejected onto the substrate (evaporation substrate) 333 mounted to the substrate support (substrate holder) 332. The distance between the nozzle 311 and the substrate is, for example, 600 mm. When the dc power supply 351, acting as plasma production means, applies a voltage of 1 kV between the sealed evaporation source 31 and the substrate 333, the vapor 342, which is in plasma state and in inverted conical form 344 (a flight shape of vapor 342), advances to the substrate 333. The CU deposited film obtained by such a method has an extremely high adhesive degree. The applied voltage of 1 kV corresponds to the plasma production energy and is an accelerating voltage. The vacuum degree prior to the evaporation was 3.5×10⁻³ Pa. The vacuum degree during evaporation was 5.5×10⁻³ Pa. That value is a sufficiently high vacuum and indicates a controlled plasma region.

In the present embodiment, the adhesive strength of Cu to the stainless steel is very strong. In the peeling test carried out to various tapes including a high adhesive tape, film peeling did not occur.

### Embodiment 2

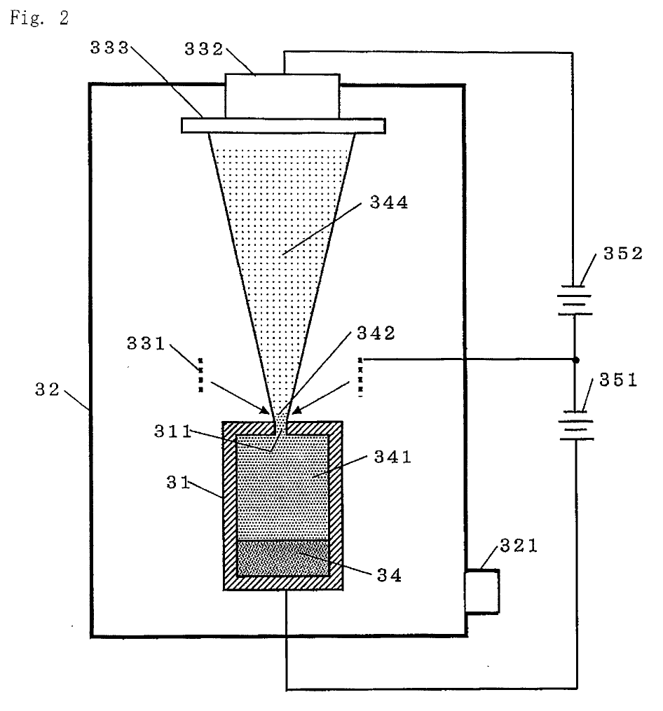

FIG. 2 shows the configuration of an evaporation apparatus according to a second embodiment of the present invention.

That configuration differs from that shown in the FIG. 1 in that; a filament 331 is added as plasma generation means near the nozzle (ejection opening) 311. Therefore, the voltage to be applied is divided into two voltages. That is, the first voltage is applied from the dc power supply 351 for the filament 331 while the second voltage is applied to the substrate 333 independently of the de power supply 351. When the filament 331 is heated with a power supply (not shown), the filament 331 emits thermal electrons to the sealed evaporation source 31. With 0.2 kV from the dc power supply 351, the vapor 342 is converted into a plasma state. The dc voltage supply 352 is used to accelerate ions in the plasma.

Other operations are similar to those in the first embodiment.

In this embodiment, the adhesive strength of Cu to a stainless steel 333 is very strong. In the peeing test to various tapes including a high adhesive tape, film peeling did not occur.

### Embodiment 3

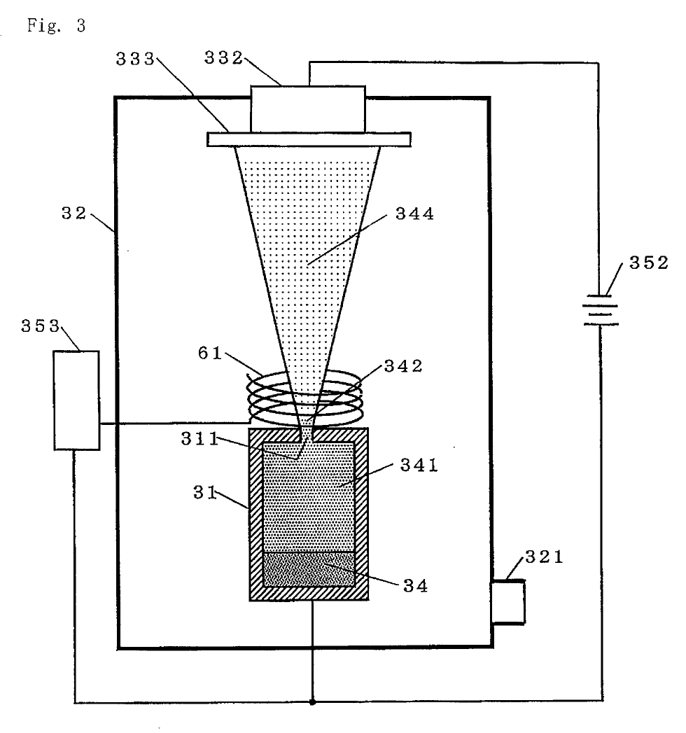

FIG. 3 shows the configuration of an evaporation apparatus according to a third embodiment of the present invention.

That configuration differs from that shown in FIG. 2 in that a high-frequency coil 61, not the filament, is disposed as plasma generation means near the nozzle 1 so as to surround the ejected vapor 342. The high-frequency power supply 353 supplies a predetermined frequency to the high-frequency coil 61. In the embodiment, a plasma state is obtained at a frequency of 13.56 MHz. The dc power supply 352 applies an accelerating voltage to the substrate 333. Other explanations are similar to those in the first embodiment.

In that embodiment, the adhesive strength of Cu to a stainless steel 333 is very strong. In the peeing test to various tapes including a high adhesive tape, film peeling did not occur.

### Embodiment 4

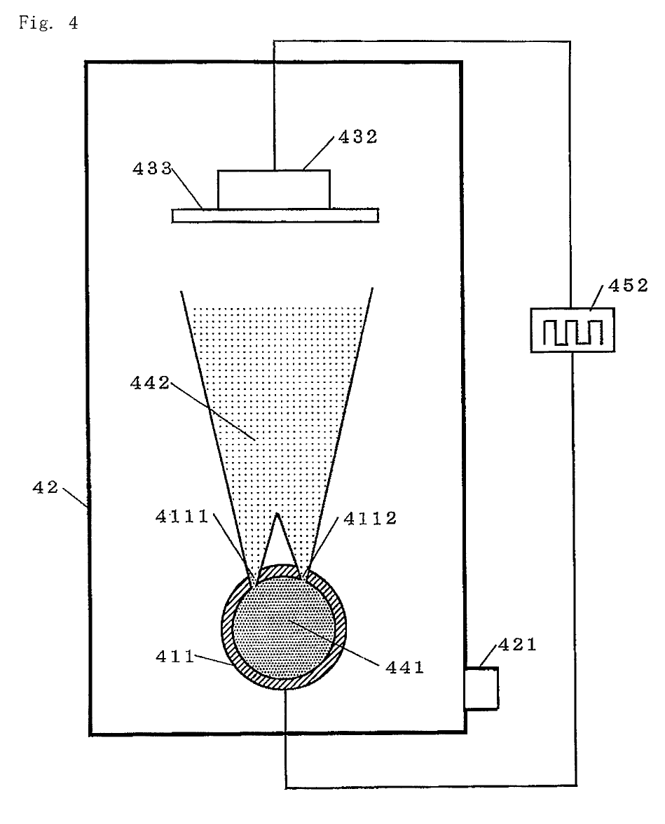

FIG. 4 shows the configuration of an evaporation apparatus according to a fourth embodiment of the present invention.

The substrate 433 is formed of an electric insulator, for example, polyester film. The evaporation material 441 is SiO gas. Deposition depending on thermal energy only does not lead to charging static electricity on the polyester film. However, when ionized SiO is deposited in the first to third embodiments, the substrate 433 is charged positive (+). As a result, the coming SIO⁺ is repelled from the substrate 433. This phenomenon cancels the generation effect of plasma. However, when the electric field in the first embodiment is positive/negative or negative/0 pulse electric field, the charging of the substrate 433 is neutralized so that the incoming SiO+ is continued.

The pulse power supply 452, or plasma generation means, applies a pulse voltage to the evaporation source 411 and the substrate 433.

In an experiment, a stable plasma state was obtained with a positive/negative pulses of a duty of ⅕, 10 KHz, and 1 KV. The adhesive strength of SiO to the polyester film surface is very strong. In the film peeling tests to various films including a high adhesive tape, film peeling did not occur.

Numerals 4111 and 4112 represent ejected openings, 42 represents a vacuum chamber, 421 represents exhaust opening, 432 represents a substrate support (substrate holder), and 442 represents an inverted conical vapor (a flight shape of an evaporation material).

### Embodiment 5

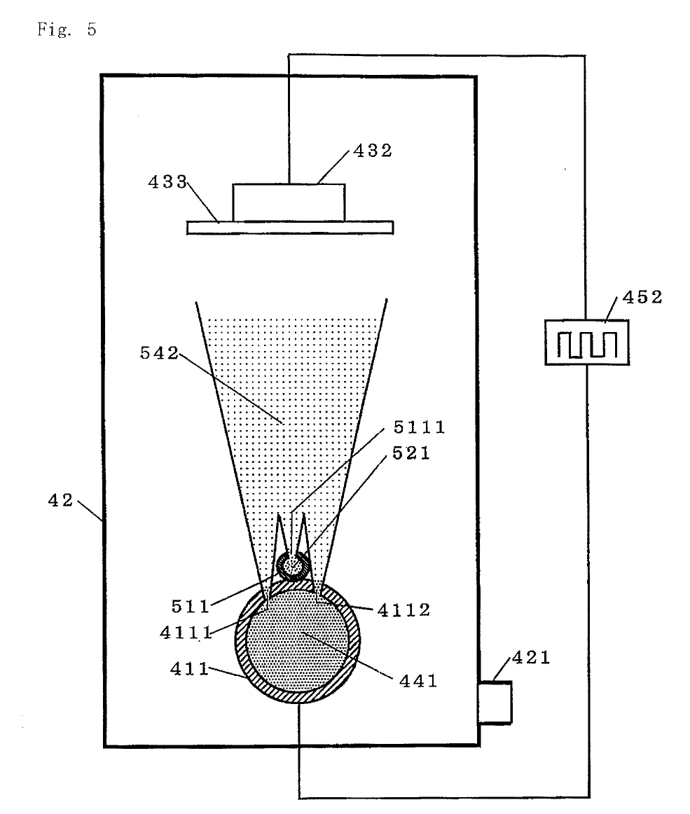

FIG. 5 shows the configuration of a fifth embodiment of the present invention. The substrate 433 is formed of an electric insulator, e.g. polyester film. The evaporation material 441 is SiO gas. SiO, which is black originally taking on sepia, provides a deposited film of sepia. The deposited film is oxidized until transparent so that the resultant film can be used as a gas barrier film for packaging.

By applying the pulse voltage with the pulse power supply 452, SiO is brought to a plasma state. Meanwhile, the reaction gas 521, or O₂, is heated, which is supplied from the reaction gas supply conduit 511, which is disposed near the ejection openings 4111 and 4112 of the evaporation source 411. Thus, the heated reaction gas 511 is ejected into the SiO plasma via the ejection opening 5111. In that state, O₂ is converted into a plasma state so that the oxidization reaction to SiO progresses better. The volume of O₂ is controlled so as to reduce sufficiently. However, this method does not deteriorate the vacuum degree in the chamber 42.

The nearly transparent SiOx deposited film, obtained in the present embodiment, has an adhesive strength as strong as the deposited film in the fourth embodiment and provides an excellent gas barrier characteristic.

Numeral 542 represents an inverted conical shape (a flight shape of an evaporation material).

The feature and function of the evaporation apparatus according to the present invention will be explained below.

The present invention takes the density of vapor ejected from the sealed evaporation source into consideration. The vapor of an evaporation material ejected from the sealed evaporation source is converted into a plasma state, without using the plasma generation gas. In the case of a sealed evaporation source, the heating temperature brings the vapor in the sealed evaporation source to a thermal disturbance, thus increasing the temperature of the sealed evaporation source. Generally, converting gas into a plasma state requires a pressure of about 10⁻¹ Pa (or more than 10⁻¹ Pa). The sealed evaporation source can easily produce the internal pressure level and the temperature thereof is increased to reach 1.33×10² Pa.

The internal pressure of the sealed evaporation source is maintained until the moment the vapor is ejected from the opening. Hence, when the plasma generation means provides an ionization energy at the ejection position, the ejected vapor is easily converted into plasma. Particularly, since the vicinity of the opening of the sealed evaporation source has a high vapor density, the ionization energy itself is can be set to a small value. Moreover, since the plasma generation gas is not required at all, the kinetic energy obtained by the thermal energy is not lost while the evaporation material does not collide with other gas molecules in the course of traveling toward the substrate. Therefore, the incident energy to the substrate is far larger than that in the normal ion plating. Since the vapor of an evaporation material does not collide with other gas molecules, the disturbance of vapor does not occur so that the use efficiency of an evaporation material is large.

In the plasma generation means of the present invention, the construction and position of electrodes, which provide an ionization energy to the ejected vapor, are not complicated, compared with the cluster ion beam technique. When a power supply, for example, a dc power supply, connected between the sealed evaporation source and the substrate applies a predetermined potential, the ejected vapor is glow charged intensively in the vicinity of the opening of the sealed evaporation source and become a plasma state. A thermal electron emission filament is used as plasma generation means. The filament is sustained in the vapor ejection area or the vicinity thereof. When a positive potential is applied to the sealed evaporation source, the thermal electrons enter the surface of the sealed evaporation source and the ejected vapor is converted into a plasma state in the progress. A high-frequency coil or a pulse power supply may be used as plasma generation means. However, the high-frequency coil, which is already used in the existing ion plating technique, can set the ionization energy to be larger than that of the thermal electrons, so that ejected vapor can be easily converted into a plasma state. Alternatively, where a pulse power supply is connected between the sealed evaporation source and the substrate to supply a pulse potential, the ejected vapor can be converted into a plasma state.

When ions in plasma is formed as a deposited film, plus static electricity accumulates on the deposited film, with an electric insulator being vapor of an evaluation material. The accumulated static electricity repels the incoming ions. In such a case, since the deposition, which utilizes ions, cannot be carried out, the static electricity has to be neutralized. Neutralization allows ions to be continuously irradiated onto the substrate. Thermal electrons can be utilized for neutralization. When the filament is heated in the vicinity of the substrate, the thermal electrons emitted from the filament toward the substrate neutralize the positive static electricity. In addition, by applying a pulse potential with a pulse power supply connected between the sealed evaporation source and the substrate to be described later, neutralization of the static electricity may be carried out.

The present invention is characterized fundamentally in that the evaporation source is of a sealed type and that the internal pressure is produced in the sealed evaporation source. No occurrence of the internal pressure in the sealed evaporation source leads to ejecting no vapor from the opening of the sealed evaporation source. The plasma area of ejected vapor due to the ejection phenomenon does not widened over the whole of the vacuum chamber and remains in the ejected vapor range (a flight range in an inverted conical shape).

The opening of the sealed evaporation source is generally a nozzle but should not be limited to the nozzle only. The opening may be a slot. The ejection velocity of ejected vapor is highest at the center of the opening. The ejection velocities at other positions are slow due to the contact resistance with the opening wall surface. Since the ejected vapor has a lowest static pressure at a highest velocity and other flows converge with the fastest velocity, the opening may be a slit, not a nozzle.

If means can be easily utilized in the vacuum deposition, conventional plasma generation means may be used regardless of various types. However, to intensively irradiate ions in plasma onto the substrate, the substrate must be maintained to a negative potential. Therefore, in configuration, the scheme of applying a potential difference by means of a power supply connected between the evaporation source and the substrate, as described previously, is preferable.

By disposing a filament in the vicinity of the ejection opening of the sealed evaporation source and irradiating thermal electrons in the ejected vapor, plasma can be obtained as described above. That method does not require an electron drawing grid, like the cluster ion beam scheme, and the sealed evaporation source has the function equivalent to the grid. Arranging the grid results in losing the electron drawing function of the grid due to the vapor adhered to the grid when the electric insulator is evaporated. However, when the sealed evaporation source itself is used as a grid, the heat of the sealed evaporation source can prevent vapor to be adhered to the grid even if the vapor reaches the sealed evaporation source. The present invention can produce plasma even when the grid is disposed. In that case, the potential difference between the substrate and the sealed evaporation source determines an acceleration amount of the ions in plasma.

The high-frequency coil has been used broadly as plasma generation means in the co-called ion plating. However, the present invention can apply the high-frequency coil, as described above. In that case, the present invention can reduce the ionization energy, compared with the ion plating technique.

The pulse power supply may apply pulses, instead of applying a potential difference with the dc power supply connected between the substrate and the sealed evaporation source. Such a case does not care about, particularly, the pulse form. By applying the pulse voltage, the ejected vapor can be converted in a plasma state. Alternatively, even if static electricity generated on the substrate due to ions, by applying positive/negative pulse or negative/zero pulse, the static electricity can be neutralized. In this manner, positive ions can impinge stationarily onto the substrate, without an effect of the static electricity.

In deposition, an oxidized film or nitride film is often formed by reacting oxygen or nitrogen with vapor. Conventionally, the reaction gas, such as oxygen or nitrogen, of an extremely small amount is diffused at the location adjacent to the substrate. In such a case, the reaction phenomenon, e.g. oxidization, often progresses on the substrate. On the other hand, it is unavoidable that the kinetic energy is lost to some extent due to a collision of the vapor of an evaporation material (a deposition material) with the reaction gas. Therefore, it is preferable to supply the reaction gas adjacent to the evaporation source. However, in the case of the open evaporation source, since the steaming area of vapor is large, it is difficult to arrange the reaction gas supply location near the evaporation source. For that reason, it has been conventionally considered that a loss of the kinetic energy is unavoidable.

In contrast, because the sealed evaporation source used in the present invention has a very small ejection opening, a reaction gas outlet can be disposed adjacent to the ejection opening. In such a configuration, the reaction gas conduit (or a reaction gas supply source) is heated by the heat of the sealed evaporation source, thus realizing the ejection phenomenon of the reaction gas. The vapor of the evaporation material (or a deposition material) and the reaction gas chemically combine with each other before both arrive to the substrate. Since the chemical combination area is in a plasma state, the reaction progresses very smoothly.

According to the present invention described above, plasma can be very easily obtained using the sealed evaporation source. The inside of the vacuum chamber is divided into a high vacuum area and an ejected vapor existing area (an inverted conical flight area). Plasma exists in only the ejected vapor existing area. The vapor travels as a whole to the substrate within a small angle and ions are attractively accelerated by the substrate potential to impinge on the substrate at a fast velocity. Accordingly, a smooth deposited film with high migration energy can be easily obtained. A very strong adhesive strength of a deposited film to the substrate can be obtained according to the applied voltage. In the oxidization and nitriding reaction, deposition can be performed while maintaining the vacuum degree as high as possible.

1. In an evaporation apparatus wherein vapor ejected from an ejection opening of a sealed evaporation source is deposited over a substrate to form an deposited film, said evaporation apparatus comprising means for converting said ejected vapor into plasma state.

2. The evaporation apparatus as defined in claim 1, wherein said means for converting ejected vapor into plasma state comprises a power supply connected between said sealed evaporation source and said substrate.

3. The evaporation apparatus as defined in claim 1, wherein said means for converting ejected vapor into plasma state comprises a thermal electron generation filament, which is disposed near said sealed evaporation source.

4. The evaporation apparatus as defined in claim 1, wherein said means for converting ejected vapor into plasma state comprises a high-frequency coil, which is disposed near said sealed evaporation source.

5. The evaporation apparatus as defined in claim 2, wherein said power supply comprises a pulse power supply.

6. The evaporation apparatus as defined in claim 1, further comprising an ejection opening for a reaction gas which is disposed near said ejection opening of said sealed evaporation source.
